(19) United States
(12) Patent Application Publication
(10) Pub. No.: US 2024/0423002 A1
(43) Pub. Date: Dec. 19, 2024

(54) PHOTOELECTRIC CONVERTER AND IMAGE SENSOR

(71) Applicant: Panasonic Intellectual Property Management Co., Ltd., Osaka (JP)

(72) Inventors: JUNJI HIRASE, Osaka (JP); HIDEYUKI UTSUMI, Osaka (JP); YUUKO TOMEKAWA, Osaka (JP); TAKANORI DOI, Kyoto (JP); SHUNSUKE ISONO, Osaka (JP)

(21) Appl. No.: 18/814,437

(22) Filed: Aug. 23, 2024

Related U.S. Application Data
(63) Continuation of application No. PCT/JP2023/006507, filed on Feb. 22, 2023.

(30) Foreign Application Priority Data
Mar. 29, 2022 (JP) 2022-054676

(51) Int. Cl. H10K 39/32

(52) U.S. Cl. CPC H10K 39/32

(57) ABSTRACT

A photoelectric converter includes a support face, and a photoelectric conversion film. The photoelectric conversion film is disposed at the support face. In a first cross-section parallel to a perpendicular direction that is perpendicular to the support face, the photoelectric conversion film has a first sloped face. In the first cross-section, the inclination angle of the first sloped face relative to a first parallel direction, which is parallel to the support face, is defined as a first slope angle. The first slope angle is greater than 0° and less than or equal to 5°.

### BACKGROUND

### 1. Technical Field

The present disclosure relates to a photoelectric converter, and an image sensor.

### 2. Description of the Related Art

Photoelectric converters with a photoelectric conversion film are known. Japanese Unexamined Patent Application Publication No. 2006-032714 and International Publication No. 2019/239851 describe performing dry etching on a photoelectric conversion film.

### SUMMARY

One non-limiting and exemplary embodiment provides a technique suitable for achieving a photoelectric converter with enhanced reliability.

In one general aspect, the techniques disclosed here feature a photoelectric converter including a support face, and a photoelectric conversion film disposed at the support face. In a first cross-section parallel to a perpendicular direction that is perpendicular to the support face, the photoelectric conversion film has a first sloped face, and when an inclination angle of the first sloped face relative to a first parallel direction parallel to the support face is defined as a first slope angle, the first slope angle is greater than 0° and less than or equal to 5°.

The technique according to the present disclosure is suitable for achieving a photoelectric converter with enhanced reliability.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a plan view of an imaging device;

FIG. 2 is a cross-sectional view of the imaging device;

FIG. 3 illustrates a detection circuit;

FIG. 4 is a plan view of a photoelectric conversion film;

FIG. 5 is a partial enlarged view of a photoelectric converter;

FIG. 6 is a partial enlarged view of the photoelectric converter;

FIG. 7 is a partial enlarged view of the photoelectric converter;

FIG. 8 is a partial enlarged view of the photoelectric converter;

FIG. 9 is a partial enlarged view of the photoelectric converter;

FIG. 10 illustrates a method for forming the photoelectric conversion film;

FIG. 11 illustrates a method for forming the photoelectric conversion film;

FIG. 12 illustrates a method for forming the photoelectric conversion film;

FIG. 13 illustrates what has been investigated;

FIG. 14 illustrates what has been investigated; and

FIG. 15 illustrates what has been investigated.

### DETAILED DESCRIPTIONS

### Underlying Knowledge Forming Basis of the Present Disclosure

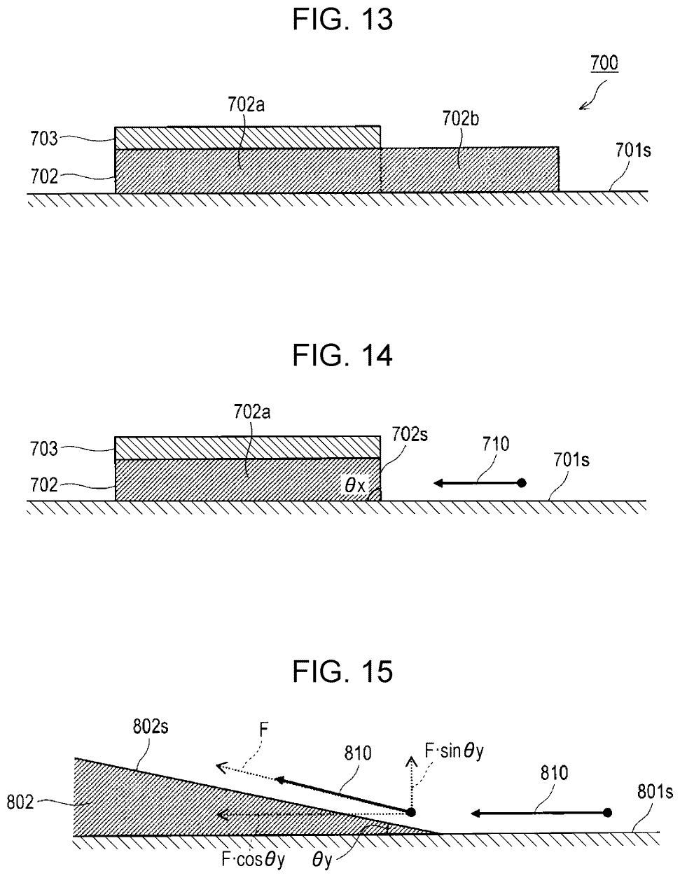

The inventors have found through intensive investigation that the angle of the lateral face of a photoelectric conversion film affects the reliability of a photoelectric converter. This is explained below with reference to FIGS. 13 to 15. FIGS. 13 to 15 each illustrate what has been investigated by the inventors.

In the example illustrated in FIG. 13, a multilayer body 700 is disposed at a support face 701s. The multilayer body 700 includes a photoelectric conversion film 702 and a mask 703, which are stacked from bottom to top in this order. The photoelectric conversion film 702 includes a first portion 702a, and a second portion 702b. The first portion 702a overlaps the mask 703 in plan view. The second portion 702b does not overlap the mask 703 in plan view.

When the multilayer body 700 is subjected to dry etching from above, the second portion 702b is removed. Thus, as illustrated in FIG. 14, the resulting photoelectric conversion film 702 includes the first portion 702a but does not include the second portion 702b. A lateral face 702s of the photoelectric conversion film 702 is inclined by an angle θx relative to the support face 701s. In the example in FIG. 14, the angle θx is about 80°.

Situations may arise where, during manufacture of a photoelectric converter, a fluid such as a cleaning solution comes into collision with a photoelectric conversion film. In the example in FIG. 15, a photoelectric conversion film 802 is disposed at a support face 801s, and a fluid 810 flows along the support face 801s toward a lateral face 802s of the photoelectric conversion film 802. The fluid 810 exerts force on the photoelectric conversion film 802 through fluid friction. This is explained in more detail below. The lateral face 802s is inclined by an angle θy relative to the support face 801s. A force F acting on the photoelectric conversion film 802 and directed along the lateral face 802s is decomposed into a force F·cos θy, which is directed parallel to the support face 801s, and a force F·sin θy, which is directed perpendicular to the support face 801s. The force F·sin θy may cause damage to the photoelectric conversion film 802.

In the example illustrated in FIG. 14, when a fluid 710 flows along the support face 701s toward the lateral face 702s of the photoelectric conversion film 702, the photoelectric conversion film 702 is subjected to a large force that is directed perpendicular to the support face 701s. This may be appreciated by substituting the large value of θx in FIG. 14, that is, θx≈80°, for the value θy of F·sin θy described above with reference to FIG. 15.

If the angle θx is large as with the example in FIG. 14, stress is more likely to concentrate at a corner of the photoelectric conversion film 702 that forms the angle θx. This means that the photoelectric conversion film 702 is less susceptible to damage when the photoelectric conversion film 702 is incorporated in a product such as a camera.

Based on the above considerations, the present disclosure provides a technique suitable for achieving a photoelectric converter with enhanced reliability.

### Overview of One Aspect of the Present Disclosure

According to a first aspect of the present disclosure, there is provided a photoelectric converter including:
a support face; and
a photoelectric conversion film disposed at the support face,
in which in a first cross-section parallel to a perpendicular direction that is perpendicular to the support face,
   the photoelectric conversion film has a first sloped face, and
   when an inclination angle of the first sloped face relative to a first parallel direction parallel to the support face is defined as a first slope angle,
   the first slope angle is greater than 0° and less than or equal to 5°.

The technique according to the first aspect is suitable for achieving a photoelectric converter with enhanced reliability.

According to a second aspect of the present disclosure, for example, in the photoelectric converter according to the first aspect,
the first slope angle may be greater than 0° and less than or equal to 1°.

The technique according to the second aspect is suitable for achieving a photoelectric converter with enhanced reliability.

According to a third aspect of the present disclosure, for example, in the photoelectric converter according to the first or second aspect,
the photoelectric conversion film may have an upper face, and
in the first cross-section, the first sloped face may be located between the upper face and the support face with respect to the perpendicular direction.

The configuration according to the third aspect is an exemplary configuration of a photoelectric converter.

According to a fourth aspect of the present disclosure, for example, in the photoelectric converter according to the third aspect,
in the first cross-section,
   when:
   a position of a lower end of the first sloped face is defined as a reference position;
   a distance between the upper face and the support face with respect to the perpendicular direction is defined as a reference distance;
   10% of the reference distance is defined as a first distance;
   a position on the first sloped face that is located upwardly away from the support face by the first distance in the perpendicular direction is defined as a first position;
   a distance between the reference position and the first position with respect to the first parallel direction is defined as a first parallel distance; and
   a distance between the reference position and the first position with respect to the perpendicular direction is defined as a first perpendicular distance,
   the first slope angle may be an arctangent of a ratio of the first perpendicular distance to the first parallel distance.

The technique according to the fourth aspect is suitable for achieving a photoelectric converter with enhanced reliability.

According to a fifth aspect of the present disclosure, for example, in the photoelectric converter according to the third aspect,
in the first cross-section,
   when:
   a position of a lower end of the first sloped face is defined as a reference position;
   a distance between the upper face and the support face with respect to the perpendicular direction is defined as a reference distance;
   20% of the reference distance is defined as a second distance;
   a position on the first sloped face that is located upwardly away from the support face by the second distance in the perpendicular direction is defined as a second position;
   a distance between the reference position and the second position with respect to the first parallel direction is defined as a second parallel distance; and
   a distance between the reference position and the second position with respect to the perpendicular direction is defined as a second perpendicular distance,
   the first slope angle may be an arctangent of a ratio of the second perpendicular distance to the second parallel distance.

The technique according to the fifth aspect is suitable for achieving a photoelectric converter with enhanced reliability.

According to a sixth aspect of the present disclosure, for example, in the photoelectric converter according to the third aspect,
in the first cross-section,
   when:
   a position of a lower end of the first sloped face is defined as a reference position;
   a distance between the upper face and the support face with respect to the perpendicular direction is defined as a reference distance;
   90% of the reference distance is defined as a third distance;
   a position on the first sloped face that is located upwardly away from the support face by the third distance in the perpendicular direction is defined as a third position;
   a distance between the reference position and the third position with respect to the first parallel direction is defined as a third parallel distance; and
   a distance between the reference position and the third position with respect to the perpendicular direction is defined as a third perpendicular distance,
   the first slope angle may be an arctangent of a ratio of the third perpendicular distance to the third parallel distance

The technique according to the sixth aspect is suitable for achieving a photoelectric converter with enhanced reliability.

According to a seventh aspect of the present disclosure, for example, in the photoelectric converter according to any one of the third to sixth aspects,
in the first cross-section, when a distance between the upper face and the support face with respect to the perpendicular direction is defined as a reference distance, the reference distance may be greater than or equal to 0.1 μm and less than or equal to 1.0 μm.

The dimension according to the seventh aspect represents an exemplary dimension observable on the photoelectric converter.

According to an eighth aspect of the present disclosure, for example, in the photoelectric converter according to any one of the first to seventh aspects,
the photoelectric conversion film may have a lower face facing the support face, and
in the first cross-section,
   the first sloped face may have a first portion and a second portion, the first portion being connected to the lower face, the second portion being located above the first portion, and
   when:
   an inclination angle of the first portion relative to the first parallel direction is defined as a first angle; and
   an inclination angle of the second portion relative to the first parallel direction is defined as a second angle,
   the first angle may be less than the second angle.

The technique according to the eighth aspect is suitable for achieving a photoelectric converter with enhanced reliability.

According to a ninth aspect of the present disclosure, for example, in the photoelectric converter according to any one of the first to eighth aspects,
the photoelectric conversion film may have a lower facing support face, and
in the first cross-section, the first sloped face may have a concave portion connected to the lower face.

The technique according to the ninth aspect is suitable for achieving a photoelectric converter with enhanced reliability.

According to a tenth aspect of the present disclosure, for example, the photoelectric converter according to any one of the first to ninth aspects may further include
an electrode,
the photoelectric conversion film may be located above the support face,
the electrode may be located above the photoelectric conversion film, and
when a region that overlaps the first sloped face in plan view is defined as a first overlap region,
in the first cross-section, the first overlap region of the electrode may have at least one face with an inclination angle greater than 0° and less than or equal to 5° relative to the first parallel direction.

The technique according to the tenth aspect is suitable for achieving a photoelectric converter with enhanced reliability.

According to an eleventh aspect of the present disclosure, for example, the photoelectric converter according to any one of the first to tenth aspects may further include
an insulating film,
the photoelectric conversion film may be located above the support face,
the insulating film may be located above the photoelectric conversion film, and
when a region that overlaps the first sloped face in plan view is defined as a first overlap region,
in the first cross-section, the first overlap region of the insulating film may have at least one face with an inclination angle greater than 0° and less than or equal to 5° relative to the first parallel direction.

The technique according to the eleventh aspect is suitable for achieving a photoelectric converter with enhanced reliability.

According to a twelfth aspect of the present disclosure, for example, the photoelectric converter according to any one of the first to eleventh aspects may further include
a light-shielding film,
the photoelectric conversion film may be located above the support face,
the light-shielding film may be located above the photoelectric conversion film, and
when a region that overlaps the first sloped face in plan view is defined as a first overlap region,
in the first cross-section, the first overlap region of the light-shielding film may have at least one face with an inclination angle greater than 0° and less than or equal to 5° relative to the first parallel direction.

The technique according to the twelfth aspect is suitable for achieving a photoelectric converter with enhanced reliability.

According to a thirteenth aspect of the present disclosure, for example, the photoelectric converter according to any one of the first to twelfth aspects may further include
an insulating layer, and
the support face may include an upper face of the insulating layer.

The configuration according to the thirteenth aspect is an exemplary configuration of a photoelectric converter.

According to a fourteenth aspect of the present disclosure, for example, in the photoelectric converter according to any one of the first to thirteenth aspects,
in the first cross-section,
   the photoelectric conversion film may have a second sloped face,
   the first sloped face may be located in an end portion of the photoelectric conversion film that projects toward one side in the first parallel direction,
   the second sloped face may be located in an end portion of the photoelectric conversion film that projects toward an other side in the first parallel direction, and
   when an inclination angle of the second sloped face relative to the first parallel direction is defined as a second slope angle,
   the second slope angle may be greater than 0° and less than or equal to 5°.

The technique according to the fourteenth aspect is suitable for achieving a photoelectric converter with enhanced reliability.

According to a fifteenth aspect of the present disclosure, for example, in the photoelectric converter according to any one of the first to fourteenth aspects,
in a second cross-section parallel to the perpendicular direction and orthogonal to the first cross-section,
   the photoelectric conversion film may have a third sloped face, and
   when an inclination angle of the third sloped face relative to a second parallel direction parallel to the support face is defined as a third slope angle,
   the third slope angle may be greater than 0° and less than or equal to 5°.

The technique according to the fifteenth aspect is suitable for achieving a photoelectric converter with enhanced reliability.

According to a sixteenth aspect of the present disclosure, for example, in the photoelectric converter according to the fifteenth aspect,
in the second cross-section,
   the photoelectric conversion film may have a fourth sloped face,
   the third sloped face may be located in an end portion of the photoelectric conversion film that projects toward one side in the second parallel direction,
   the fourth sloped face may be located in an end portion of the photoelectric conversion film that projects toward an other side in the second parallel direction, and
   when an inclination angle of the fourth sloped face relative to the second parallel direction is defined as a fourth slope angle,
   the fourth slope angle may be greater than 0° and less than or equal to 5°.

The technique according to the sixteenth aspect is suitable for achieving a photoelectric converter with enhanced reliability.

An image sensor according to a seventeenth aspect of the present disclosure includes:
the photoelectric converter according to any one of the first to sixteenth aspects; and
a detection circuit that extracts a signal, the signal being generated through photoelectric conversion in the photoelectric conversion film.

The technique according to the seventeenth aspect is suitable for achieving an image sensor with enhanced reliability.

In the following description, “upper”, “lower”, “perpendicular”, “horizontal”, “lateral”, and other similar terms are used solely to specify the relative positioning of components, and are not intended to limit how such components are oriented when the photoelectric converter is in use.

In the following description of embodiments, ordinals such as first, second, third, and so on are sometimes used. When an ordinal is attached to a certain element, it is not necessarily required for the same kind of element with a smaller ordinal number to exist. Ordinal numbers can be changed, added, or deleted as required.

As used hereinafter, the term “plan view” refers to a view seen in a direction perpendicular to the support face.

As used hereinafter, the expression “Element A includes Element B” means that Element A includes at least part of Element B. The same applies to the expressions “Element A has Element B” and “Element A comprises Element B.” When it is stated herein that Element A and Element B overlap in plan view, this means that at least part of Element A and at least part of Element B overlap in plan view.

The drawings do not necessarily depict individual features to exact scale. Illustrations of some elements may be omitted in the drawings. In the drawings, dimensions, slope angles, or other details may be depicted in an exaggerated manner. Hereinafter, the same reference signs are used to designate constituent elements that are substantially identical in function, and repetitive descriptions may be omitted or simplified.

### Embodiments

An imaging device according to embodiments of the present disclosure is described below with reference to the drawings.

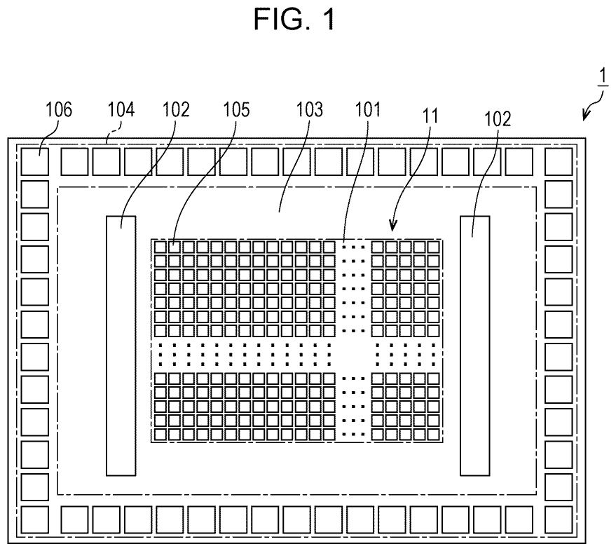

FIG. 1 is a plan view of an imaging device 1. The imaging device 1 includes a pixel region 101, a counter electrode region 102, a peripheral circuit region 103, and a peripheral pad region 104. In the pixel region 101, pixel electrodes 517 are arranged in matrix form, and pixels are thus in matrix form. In the counter electrode region 102, voltage is applied to a counter electrode 519. A peripheral circuit is disposed in the peripheral circuit region 103. The peripheral circuit includes a driving circuit, a vertical scanning circuit, and a horizontal signal readout circuit. The driving circuit supplies voltage to the counter electrode 519. The vertical scanning circuit selects a pixel row from which a signal is to be read out. The horizontal signal readout circuit extracts a signal from a detection circuit 570. Peripheral pads 106 are arranged in the peripheral pad region 104.

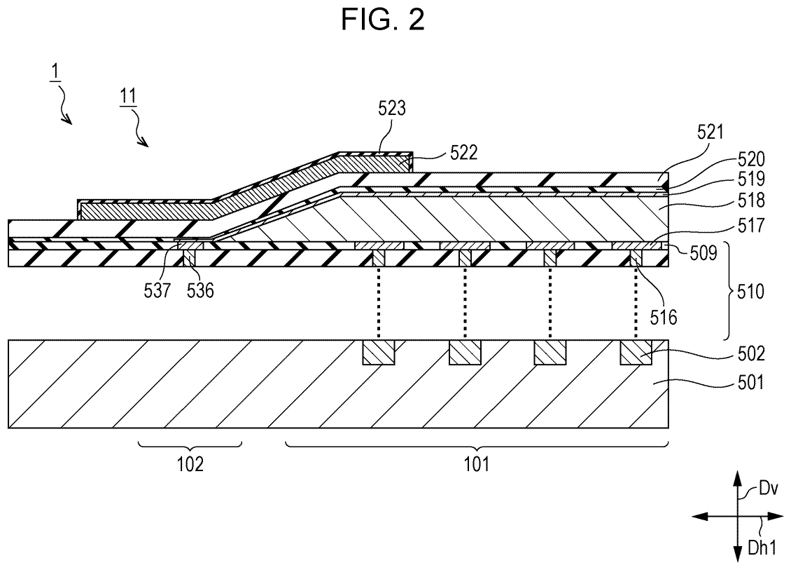

FIG. 2 is a cross-sectional view of the imaging device 1. In the pixel region 101, a semiconductor substrate 501 is provided with charge storage parts 502. An insulating structure 510 is disposed above the semiconductor substrate 501. The insulating structure 510 includes insulating layers. An insulating layer 509 is one of the insulating layers. More specifically, the insulating layer 509 is the uppermost one of the insulating layers. According to the embodiments, each charge storage part 502 is a diffusion region.

The semiconductor substrate 501 includes a semiconductor material. The semiconductor material is, for example, silicon (Si). According to the embodiments, the semiconductor substrate 501 includes silicon.

Each of the insulating layers includes an insulating material. The insulating material is, for example, silicon oxide (SiO₂) or tetraethyl orthosilicate (TEOS). According to the embodiments, each of the insulating layers includes tetraethyl orthosilicate.

In the pixel region 101, pixel plugs 516 are disposed within the insulating structure 510. Pixel electrodes 517 are disposed above the pixel plugs 516. In each of the pixels, the charge storage part 502, the pixel plug 516, and the pixel electrode 517 are electrically connected. A photoelectric conversion film 518 is disposed so as to cover the pixel plugs 516. The photoelectric conversion film 518, the counter electrode 519, a first insulating film 520, and a second insulating film 521 are stacked in this order from bottom to top.

Each pixel plug 516 may include a metal. The metal is, for example, copper (Cu) or tungsten (W). According to the embodiments, the pixel plug 516 include copper.

Each pixel electrode 517 may include at least one selected from the group consisting of a metal and a metal compound. The metal is, for example, titanium (Ti), tantalum (Ta), or aluminum (Al). The metal compound is, for example, metal nitride. The metal nitride is, for example, titanium nitride (TiN) or tantalum nitride (TaN). The pixel electrodes 517 may include polysilicon to which conductivity has been imparted by doping with impurities. According to the embodiments, the pixel electrodes 517 have a multilayer structure. The multilayer structure includes a first layer, which includes titanium, and a second layer, which includes titanium nitride. The first layer is in contact with the photoelectric conversion film 518. The second layer is in contact with the corresponding pixel plug 516.

Typically, the photoelectric conversion film 518 includes an organic semiconductor. The photoelectric conversion film 518 may include one or more organic semiconductor layers. For example, the photoelectric conversion film 518 may include, in addition to a photoelectric conversion layer that generates hole-electron pairs, a carrier transport layer that transports electrons or holes, a blocking layer that blocks electrons or holes, or other layers. As for the organic semiconductor layer, an organic p-type semiconductor and an organic n-type semiconductor that are made of a known material may be used. The photoelectric conversion film 518 may be, for example, a film mixture of organic donor molecules and acceptor molecules, a film mixture of a carbon nanotube semiconductor and acceptor molecules, or a quantum dot-containing film. The photoelectric conversion film 518 may include an inorganic material such as amorphous silicon. According to the embodiments, the photoelectric conversion film 518 includes an organic semiconductor.

The counter electrode 519 includes a light-transmissive conductive material. The conductive material included in the counter electrode 519 is, for example, indium tin oxide (ITO) or indium zinc oxide (IZO). According to the embodiments, the counter electrode 519 includes ITO.

According to the embodiments, the first insulating film 520 includes aluminum oxide (AlO). The second insulating film 521 includes silicon oxynitride (SiON).

A light-shielding film 522 is disposed so as to cover part of the second insulating film 521 from above. In the illustrated example, in plan view, the light-shielding film 522 overlaps at least one pixel electrode 517. A pixel including the pixel electrode 517 that overlaps the light-shielding film 522 may serve as an optical black pixel. The light-shielding film 522 is covered by a third insulating film 523 from above and from lateral sides.

The light-shielding film 522 may include at least one selected from the group consisting of a metal and a metal compound. For example, the light-shielding film 522 may include at least one selected from the group consisting of titanium (Ti), titanium nitride (TiN), aluminum (Al), silicon (Si), copper-added aluminum (AlSiCu), copper (Cu), and tungsten (W). The light-shielding film 522 may include an alloy including at least two of the above-listed specific examples of materials. The light-shielding film 522 may have a single-layer structure, or may have a multilayer structure. According to the embodiments, the light-shielding film 522 has a multilayer structure that includes a layer including titanium, and a layer including a titanium compound. According to the embodiments, the third insulating film 523 includes silicon oxynitride (SiON).

Although not illustrated, in the pixel region 101, a color filter is disposed above the second insulating film 521. Further, a microlens is disposed above the color filter. Light impinges on the photoelectric conversion film 518 from above via the microlens, the color filter, the second insulating film 521, the first insulating film 520, and the counter electrode 519.

In the counter electrode region 102, a connection plug 536 is disposed within the insulating structure 510. A connection electrode 537 is disposed above the connection plug 536. The counter electrode 519 is disposed above the connection electrode 537. The connection plug 536, the connection electrode 537, and the counter electrode 519 are electrically connected.

The connection plug 536 may include a metal. The metal is, for example, copper (Cu) or tungsten (W). According to the embodiments, the connection plug 536 includes copper.

The connection electrode 537 may include at least one selected from the group consisting of a metal and a metal compound. The metal is, for example, titanium (Ti), tantalum (Ta), or aluminum (Al). The metal compound is, for example, metal nitride. The metal nitride is, for example, titanium nitride (TiN) or tantalum nitride (TaN). The connection electrode 537 may include polysilicon to which conductivity has been imparted by doping with impurities. According to the embodiments, the connection electrode 537 has a multilayer structure. The multilayer structure includes a third layer, which includes titanium, and a fourth layer, which includes titanium nitride. The third layer is in contact with the counter electrode 519. The fourth layer is in contact with the connection plug 536.

Voltage is applied to the counter electrode 519 via the connection plug 536 and the connection electrode 537. An electric field is thus applied to the photoelectric conversion film 518, which is located between the counter electrode 519 and each pixel electrode 517. When light impinges on the photoelectric conversion film 518 from above in this state, photoelectric conversion takes place in the photoelectric conversion film 518, and a charge generated through the photoelectric conversion is collected by the pixel electrode 517. The charge is sent from the pixel electrode 517 to the corresponding charge storage part 502 via the pixel plug 516 for storage into the charge storage part 502. By means of the detection circuit 570, a signal proportional to a voltage at the charge storage part 502 is output externally at appropriate times. The detection circuit 570 is disposed at each pixel.

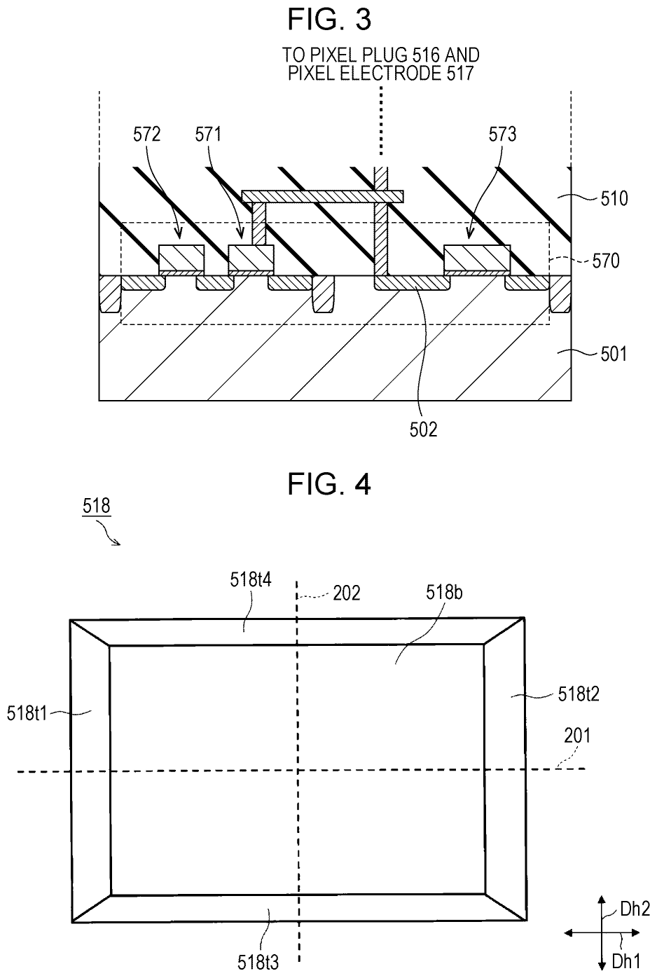

FIG. 3 illustrates the detection circuit 570. The detection circuit 570 includes the charge storage part 502. The detection circuit 570 also includes an amplification transistor 571, an address transistor 572, and a reset transistor 573. One of the source and drain of the reset transistor 573 constitutes the charge storage part 502. The charge storage part 502 is electrically connected to the gate electrode of the amplification transistor 571. The amplification transistor 571 and the address transistor 572 are electrically connected within the semiconductor substrate 501. The amplification transistor 571 outputs a signal proportional to the voltage at the charge storage part 502. The address transistor 572 determines the timing at which the amplification transistor 571 outputs a signal. The reset transistor 573 resets the voltage at the charge storage part 502. According to the embodiments, each of the amplification transistor 571, the address transistor 572, and the reset transistor 573 is a metal-oxide-semiconductor field-effect transistor (MOSFET).

Hereinafter, a non-limiting exemplary configuration of the imaging device 1 is further described by using the following terms: an image sensor 11 and a photoelectric converter 21.

The photoelectric converter 21 includes the pixel electrodes 517, the photoelectric conversion film 518, the counter electrode 519, the first insulating film 520, the second insulating film 521, the color filter, the microlens, the light-shielding film 522, the third insulating film 523, and the connection electrode 537. The image sensor 11 includes the photoelectric converter 21, the pixel plugs 516, the connection plug 536, and the detection circuit 570. The detection circuit 570 of the image sensor 11 extracts a signal generated through photoelectric conversion in the photoelectric converter 21. The imaging device 1 includes the image sensor 11, the peripheral circuit, and the peripheral pads 106.

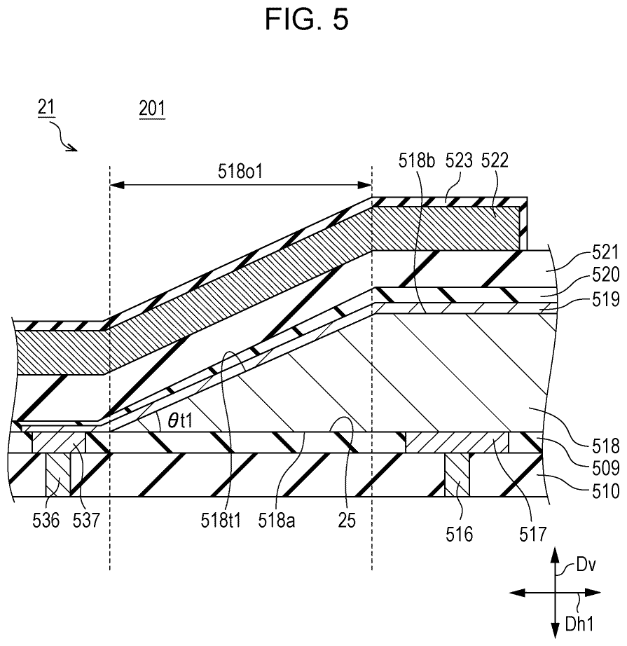

FIG. 4 is a plan view of the photoelectric conversion film 518. FIGS. 5 to 9 are partial enlarged views of the photoelectric converter 21.

As illustrated in FIG. 5, the photoelectric converter 21 includes a support face 25, and the photoelectric conversion film 518. The photoelectric conversion film 518 is disposed at the support face 25. In a first cross-section 201 parallel to a perpendicular direction Dv, which is a direction perpendicular to the support face 25, the photoelectric conversion film 518 has a first sloped face 518t1. In the first cross-section 201, the inclination angle of the first sloped face 518t1 relative to a first parallel direction Dh1, which is a direction parallel to the support face 25, is defined as a first slope angle θt1. The first slope angle θt1 is greater than 0° and less than or equal to 5°. This configuration is suitable for achieving the photoelectric converter 21 with enhanced reliability. The first slope angle θt1 may be greater than 0° and less than or equal to 1°.

The reasons why the above-mentioned configuration is suitable for achieving the photoelectric converter 21 with enhanced reliability are described below. First, a case is considered where, during manufacture of the photoelectric converter 21, a fluid such as a cleaning solution flows along the support face 25 toward the first sloped face 518t1 of the photoelectric conversion film 518. Even if such a flow occurs, the small first slope angle θt1 mentioned above means that a force directed away from the support face 25 is less likely to act on the photoelectric conversion film 518. This may mitigate damage to the photoelectric conversion film 518. Second, due to the small first slope angle θt1 mentioned above, stress is more likely to concentrate at a corner of the photoelectric conversion film 518 that forms the first slope angle θt1. This means that the photoelectric conversion film 518 is less susceptible to damage when the photoelectric converter 21 is incorporated in a product such as a camera.

A quantitative explanation of the reasons mentioned above is given below, as contrasted with the example described above with reference to FIG. 14. In the example in FIG. 14, θx≈80°. In this example, sin 80°≈0.985. In the example described above with reference to FIG. 5, θt1≤5° or θt1≤1°. In this example, sin 5°≈0.087, which is a value less than one-tenth of 0.985. In this example, sin 1°≈0.017, which is a value less than one-fiftieth of 0.985. It may be thus quantitatively appreciated that the example in FIG. 5 facilitates achieving a photoelectric converter with enhanced reliability than does the example in FIG. 14.

As may be appreciated from the above description, the lower limit of the first slope angle θt1 is greater than 0°. The lower limit of the first slope angle θt1 may be 0.1°, or may be 0.2°. That is, the first slope angle θt1 may be greater than or equal to 0.1° and less than or equal to 5°, may be greater than or equal to 0.2° and less than or equal to 5°, may be greater than or equal to 0.1° and less than or equal to 1°, or may be greater than or equal to 0.2° and less than or equal to 1°. Making the first slope angle θt1 greater than or equal to 0.1° or greater than or equal to 0.2° facilitates mitigating the length of the first sloped face 518t1 with respect to the first parallel direction Dh1, and consequently facilitates mitigating the surface area of the photoelectric converter 21.

In the example in FIG. 14, the lateral face 702s is in the form of a wall that extends substantially perpendicular to the support face 701s. In contrast, in the example in FIG. 5, the first sloped face 518t1 extends in a direction close to the first parallel direction Dh1.

The support face 25 includes the upper face of the insulating layer 509. The support face 25 includes the upper face of each pixel electrode 517. The support face 25 includes the upper face of the connection electrode 537.

The photoelectric conversion film 518 is located above the support face 25. The photoelectric conversion film 518 has a lower face 518a, and an upper face 518b. In the first cross-section 201, the first sloped face 518t1 is located between the upper face 518b and the support face 25 with respect to the perpendicular direction Dv. The upper face 518b may include the first sloped face 518t1. In the first cross-section 201, the inclination angle of the upper face 518b relative to the first parallel direction Dh1 may be less than the first slope angle θt1. For example, the above-mentioned inclination angle may be greater than or equal to 0° and less than 0.1°, may be greater than or equal to 0° and less than or equal to 0.05°, or may be greater than or equal to 0° and less than or equal to 0.03°. The lower face 518a faces the support face 25. More specifically, the lower face 518a is in contact with the support face 25. In the first cross-section 201, the first sloped face 518t1 connects the lower face 518a and the upper face 518b .

The first slope angle θt1 may be based on a first definition, a second definition, or a third definition described below. According to the embodiments, if it can be said that “the first slope angle θt1 is greater than 0° and less than or equal to 5°”based on at least one of the first definition, the second definition, or the third definition, then it is regarded that “the first slope angle θt1 is greater than 0° and less than or equal to 5°.” The same applies to other expressions related to the first slope angle θt1.

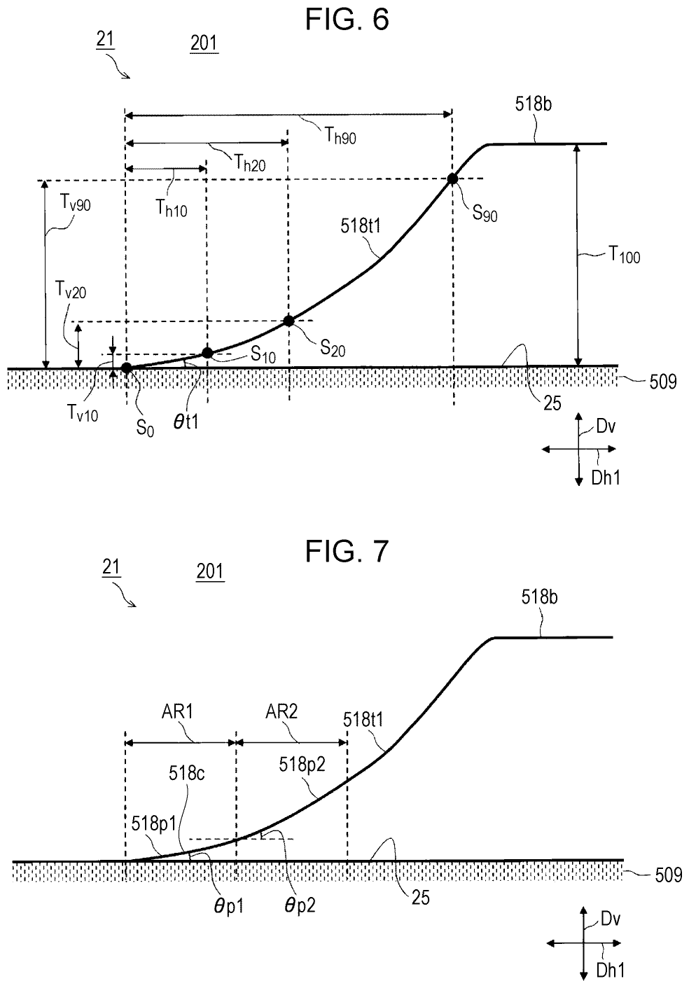

The first definition, the second definition, and the third definition are described below with reference to FIG. 6. In the first cross-section 201, the position of the lower end of the first sloped face 518t1 is defined as a reference position So. In the first cross-section 201, the distance between the upper face 518b and the support face 25 with respect to the perpendicular direction Dv is defined as a reference distance T₁₀₀.

With regard to the first definition, 10% of the reference distance T₁₀₀ is defined as a first distance. In the first cross-section 201, a position on the first sloped face 518t1 that is located upwardly away from the support face 25 by the first distance in the perpendicular direction Dv is defined as a first position S₁₀. In the first cross-section 201, the distance between the reference position S₀ and the first position S₁₀ with respect to the first parallel direction Dh1, and the distance between the reference position S₀ and the first position S₁₀ with respect to the perpendicular direction Dv are respectively defined as a first parallel distance Tₕ₁₀ and a first perpendicular distance Tᵥ₁₀. According to the first definition, the first slope angle θt1 is the arctangent of the ratio of the first perpendicular distance Tᵥ₁₀ to the first parallel distance Tₕ₁₀. That is, according to the first definition, the first slope angle θt1 is given by Equation 1 below.

$$θ t 1 = {tan}^{- 1} ( {T}_{v 10} / {T}_{h 10} ) \qquad Equation 1$$

With regard to the second definition, 20% of the reference distance T₁₀₀ is defined as a second distance. In the first cross-section 201, a position on the first sloped face 518t1 that is located upwardly away from the support face 25 by the second distance in the perpendicular direction Dv is defined as a second position S₂₀. In the first cross-section 201, the distance between the reference position So and the second position S₂₀ with respect to the first parallel direction Dh1, and the distance between the reference position S₀ and the second position S₂₀ with respect to the perpendicular direction Dv are respectively defined as a second parallel distance Tₕ₂₀ and a second perpendicular distance Tᵥ₂₀. According to the second definition, the first slope angle θt1 is the arctangent of the ratio of the second perpendicular distance Tᵥ₂₀ to the second parallel distance Tₕ₂₀. That is, according to the second definition, the first slope angle θt1 is given by Equation 2 below.

$$θ t 1 = {tan}^{- 1} ( {T}_{v 20} / {T}_{h 20} ) \qquad Equation 2$$

With regard to the third definition, 90% of the reference distance T₁₀₀ is defined as a third distance. In the first cross-section 201, a position on the first sloped face 518t1 that is located upwardly away from the support face 25 by the third distance in the perpendicular direction Dv is defined as a third position S₉₀. In the first cross-section 201, the distance between the reference position S₀ and the third position S₉₀ with respect to the first parallel direction Dh1, and the distance between the reference position S₀ and the third position S₉₀ with respect to the perpendicular direction Dv are respectively defined as a third parallel distance Tₕ₉₀ and a third perpendicular distance Tᵥ₉₀. According to the third definition, the first slope angle θt1 is the arctangent of the ratio of the third perpendicular distance Tᵥ₉₀ to the third parallel distance Tₕ₉₀. That is, according to the third definition, the first slope angle θt1 is given by Equation 3 below.

$$θ t 1 = {tan}^{- 1} ( {T}_{v 90} / {T}_{h 90} ) \qquad Equation 3$$

The above-mentioned range of the first slope angle θt1, that is, 0 <θt1≤5° or 0<θt1≤1°, is a very low angular range. Accordingly, the first slope angle θt1 based on any one of the first definition, the second definition, and the third definition may provide an effect sufficient to attain the reliability of the photoelectric converter 21.

In the first cross-section 201, the reference distance T₁₀₀ is, for example, greater than or equal to 0.1 μm and less than or equal to 1.0 μm. The reference distance T₁₀₀ may be greater than or equal to 0.2 μm and less than or equal to 0.7 μm.

As illustrated in FIG. 7, in the first cross-section 201, the first sloped face 518t1 has a first portion 518p1, and a second portion 518p2. The first portion 518p1 is connected to the lower face 518a. The second portion 518p2 is located above the first portion 518p1. In the first cross-section 201, the inclination angle of the first portion 518p1 relative to the first parallel direction Dh1 is defined as a first angle θp1. In the first cross-section 201, the inclination angle of the second portion 518p2 relative to the first parallel direction Dh1 is defined as a second angle θp2. The first angle θp1 is less than the second angle θp2. This configuration facilitates ensuring that in the first cross-section 201, the direction in which the first sloped face 518t1 extends in the vicinity of the lower end of the first sloped face 518t1 is close to the first parallel direction Dh1. This is suitable for achieving the photoelectric converter 21 with enhanced reliability. In the example in FIG. 7, the first portion 518p1 and the second portion 518p2 are connected. Alternatively, however, the first portion 518p1 and the second portion 518p2 may be spaced apart from each other. In FIG. 7, a first arrow AR1 and a second arrow AR2 respectively represent, with respect to the first parallel direction Dh1, the extent of an area where the first portion 518p1 exists, and the extent of an area where the second portion 518p2 exists.

For the definition of the first angle θp1, the first definition, the second definition, and the third definition mentioned above with respect to the first slope angle θt1 can be used by being redefined as described below. More specifically, the following terms can be redefined as follows:
The term “first sloped face 518t1” can be read as “first portion 518p1.”;
The term “the reference distance T₁₀₀ between the upper face 518b and the support face 25 with respect to the perpendicular direction Dv” can be read as “the distance between the lower end and the upper end of the first portion 518p1 with respect to the perpendicular direction Dv.”; and
The term “first slope angle θt1” can be read as “first angle θp1.”

As for the definition of the second angle θp2, the first definition, the second definition, and the third definition mentioned above with respect to the first slope angle θt1 can be redefined as described below. More specifically, the following terms can be redefined as follows:
The term “first sloped face 518t1” can be read as “the second portion 518p2.”;
The term “the reference distance T₁₀₀ between the upper face 518b and the support face 25 with respect to the perpendicular direction Dv” can be read as “the distance between the lower end and the upper end of the second portion 518p2 with respect to the perpendicular direction Dv.”; and
The term “first slope angle θt1” can be read as “second angle θp2.”

According to the embodiments, if it can be said that “the angle θp1 is less than the second angle θp2” based on at least one of the redefined version of the first definition, the redefined version of the second definition, or the redefined version of the third definition, then it is regarded that “the first angle θp1 is less than the second angle θp2.”

As illustrated in FIG. 7, in the first cross-section 201, the first sloped face 518t1 has a concave portion 518c connected to the lower face 518a. This configuration facilitates ensuring that in the first cross-section 201, the direction in which the first sloped face 518t1 extends in the vicinity of the lower end of the first sloped face 518t1 is close to the first parallel direction Dh1. This is suitable for achieving the photoelectric converter 21 with enhanced reliability.

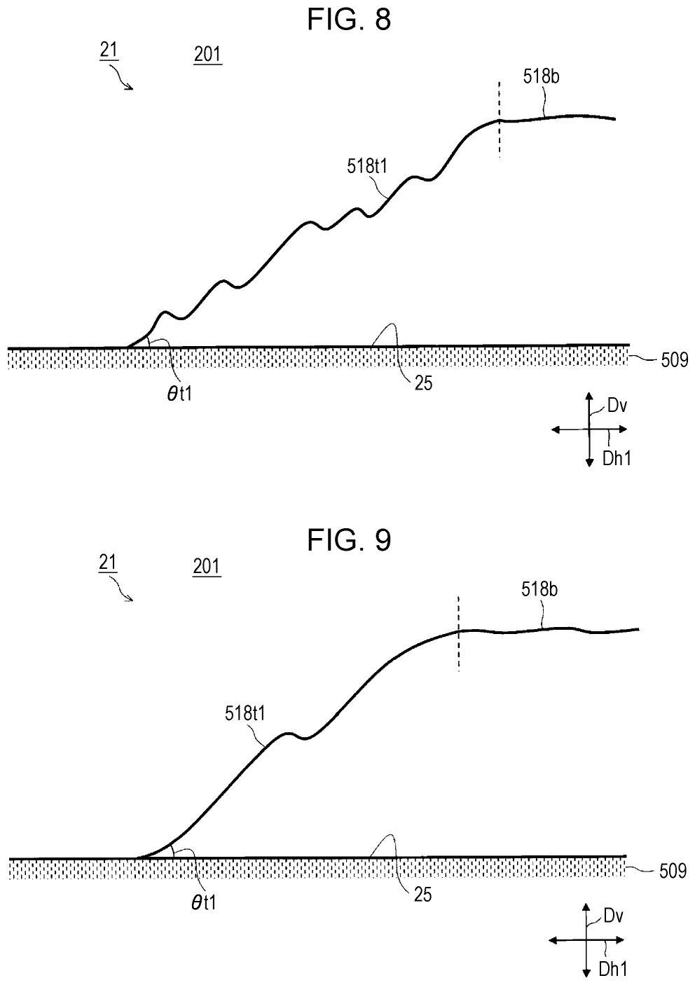

More specifically, as illustrated in FIGS. 8 and 9, in the first cross-section 201, the first sloped face 518t1 may be undulated. When it is stated herein that the first sloped face 518t1 is undulated in the first cross-section 201, this means that in the first cross-section 201, the first sloped face 518t1 has at least one projection and at least one depression. This may make it possible to, when the photoelectric conversion film 518 is in contact at its first sloped face 518t1 with another component, increase the area of contact between the photoelectric conversion film 518 and the other component, and consequently to increase the strength of bonding therebetween. The component in this case is, for example, the counter electrode 519. In FIGS. 8 and 9, the boundary between the first sloped face 518t1 and the upper face 518b is represented by a dotted line for convenience.

A more detailed description is given below of the reference distance T₁₀₀described above with reference to FIG. 6, which is the distance between the upper face 518b and the support face 25 with respect to the perpendicular direction Dv. As illustrated in FIGS. 7 and 8, the upper face 518b may be not perfectly flat in some cases. In such cases, the maximum distance between the upper face 518b and the support face 25 with respect to the perpendicular direction Dv is regarded as the reference distance T₁₀₀.

Referring back to FIG. 5, a region that overlaps the first sloped face 518t1 in plan view is defined as a first overlap region 518o1.

As illustrated in FIG. 5, the counter electrode 519 is located above the photoelectric conversion film 518. In the first cross-section 201, the first overlap region 518o1 of the counter electrode 519 has at least one face with an inclination angle greater than 0° and less than or equal to 5° relative to the first parallel direction Dh1. This configuration is suitable for achieving the photoelectric converter 21 with enhanced reliability. For example, this configuration facilitates ensuring adequate coverage by the counter electrode 519. Further, for example, this configuration facilitates reducing potential stress on the counter electrode 519. This facilitates ensuring the conductivity of the counter electrode 519. The above-mentioned inclination angle may be greater than 0° and less than or equal to 1°. The lower limit of the above-mentioned inclination angle may be 0.1°, or may be 0.2°. In the example illustrated in FIG. 5, the at least one face includes two faces, and more specifically refers to two faces. One of the two faces is located at a relatively low position, and the other is located at a relative high position.

As illustrated in FIG. 5, the first insulating film 520 is located above the photoelectric conversion film 518. In the first cross-section 201, the first overlap region 518o1 of the first insulating film 520 has at least one face with an inclination angle greater than 0° and less than or equal to 5° relative to the first parallel direction Dh1. This configuration is suitable for achieving the photoelectric converter 21 with enhanced reliability. For example, this configuration facilitates ensuring adequate coverage by the first insulating film 520, and facilitates ensuring close contact between the first insulating film 520 and the film located under the first insulating film 520. Further, for example, this configuration facilitates reducing potential stress on the first insulating film 520. This facilitates ensuring the moisture resistance and insulating properties of the first insulating film 520. The above-mentioned inclination angle may be greater than 0° and less than or equal to 1°. The lower limit of the above-mentioned inclination angle may be 0.1°, or may be 0.2°. In the example illustrated in FIG. 5, the at least one face includes two faces, and more specifically refers to two faces. One of the two faces is located at a relatively low position, and the other is located at a relative high position.

As illustrated in FIG. 5, the second insulating film 521 is located above the photoelectric conversion film 518. In the first cross-section 201, the first overlap region 518o1 of the second insulating film 521 has at least one face with an inclination angle greater than 0° and less than or equal to 5° relative to the first parallel direction Dh1. This configuration is suitable for achieving the photoelectric converter 21 with enhanced reliability. For example, this configuration facilitates ensuring adequate coverage by the second insulating film 521, and facilitates ensuring close contact between the second insulating film 521 and the film located under the second insulating film 521. Further, for example, this configuration facilitates reducing potential stress on the second insulating film 521. This facilitates ensuring the moisture resistance and insulating properties of the second insulating film 521. The above-mentioned inclination angle may be greater than 0° and less than or equal to 1°. The lower limit of the above-mentioned inclination angle may be 0.1°, or may be 0.2°. In the example illustrated in FIG. 5, the at least one face includes two faces, and more specifically refers to two faces. One of the two faces is located at a relatively low position, and the other is located at a relative high position.

As illustrated in FIG. 5, the light-shielding film 522 is located above the photoelectric conversion film 518. In the first cross-section 201, the first overlap region 518o1 of the light-shielding film 522 has at least one face with an inclination angle greater than 0° and less than or equal to 5° relative to the first parallel direction Dh1. This configuration is suitable for achieving the photoelectric converter 21 with enhanced reliability. For example, this configuration facilitates reducing potential stress on the light-shielding film 522, and consequently facilitates reducing potential cracking or other defects in the light-shielding film 522. This facilitates ensuring the light-blocking properties of the light-shielding film 522. The above-mentioned inclination angle may be greater than 0° and less than or equal to 1°. The lower limit of the above-mentioned inclination angle may be 0.1°, or may be 0.2°. In the example illustrated in FIG. 5, the at least one face includes two faces, and more specifically refers to two faces. One of the two faces is located at a relatively low position, and the other is located at a relative high position.

In the example illustrated in FIG. 5, in the first overlap region 518o1, the following faces are arranged from bottom to top in the order stated below: the first sloped face 518t1; one of the two faces of the counter electrode 519; the other of the two faces of the counter electrode 519; one of the two faces of the first insulating film 520; the other of the two faces of the first insulating film 520; one of the two faces of the second insulating film 521; the other of the two faces of the second insulating film 521; one of the two faces of the light-shielding film 522; and the other of the two faces of the light-shielding film 522. As for the respective inclination angles of these faces relative to the first parallel direction Dh1 in the first cross-section 201, the first definition, the second definition, and the third definition mentioned above with respect to the first slope angle θt1 can be used also for these inclination angles.

As illustrated in FIG. 4, in the first cross-section 201, the photoelectric conversion film 518 has a second sloped face 518t2. In the first cross-section 201, the first sloped face 518t1 is located in an end portion of the photoelectric conversion film 518 that projects toward one side in the first parallel direction Dh1. In the first cross-section 201, the second sloped face 518t2 is located in an end portion of the photoelectric conversion film 518 that projects toward the other side in the first parallel direction Dh1. The description given above with regard to the first sloped face 518t1 is applicable in part or in whole to the second sloped face 518t2.

As illustrated in FIG. 4, in a second cross-section 202 parallel to the perpendicular direction Dv and orthogonal to the first cross-section 201, the photoelectric conversion film 518 has a third sloped face 518t3, and a fourth sloped face 518t4. In the second cross- section 202, the third sloped face 518t3 is located in an end portion of the photoelectric conversion film 518 that projects toward one side in a second parallel direction Dh2, which is a direction parallel to the support face 25. In the second cross-section 202, the fourth sloped face 518t4 is located in an end portion of the photoelectric conversion film 518 that projects toward the other side in the second parallel direction Dh2. The description given above with regard to the first sloped face 518t1 is applicable in part or in whole to the third sloped face 518t3 and the fourth sloped face 518t4.

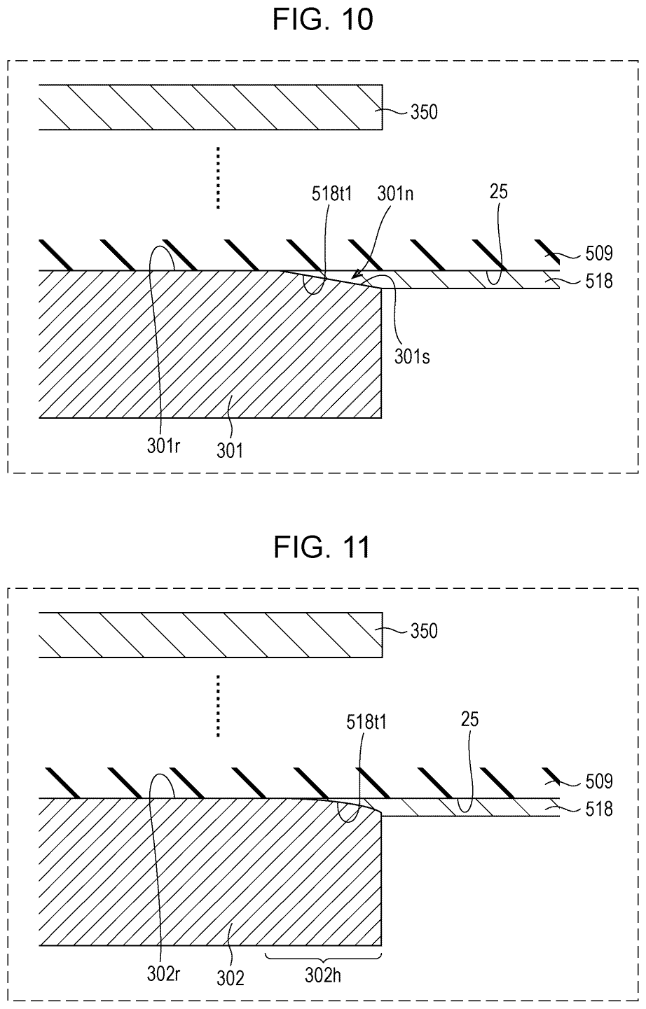

A non-limiting example of a method for forming the photoelectric conversion film 518 is described below with reference to FIGS. 10 to 12. FIGS. 10 to 12 each illustrate a method for forming the photoelectric conversion film 518.

A first forming method, a second forming method, and a third forming method respectively use a first shadow mask 301, a second shadow mask 302, and a third shadow mask 303. The first to third shadow masks 301 to 303 include a metal. The first to third shadow masks 301 to 303 are disposed vertically below the support face 25. The material for the photoelectric conversion film 518 is supplied by vacuum deposition generally from a vertically lower position toward a vertically higher position. This facilitates ensuring that even when foreign matter adheres to the photoelectric conversion film 518, such foreign matter is allowed to fall. Although the material is initially ejected so as to move in a nearly vertical direction, the direction of material movement may subsequently deviate from the vertical direction. This is presumably because collisions between ejected material particles cause the direction of material movement to change.

The first forming method illustrated in FIG. 10 is vacuum deposition using the first shadow mask 301. The first shadow mask 301 has a reference face 301r, and a sloped face 301s. The sloped face 301s defines a notch 301n in the first shadow mask 301. As seen from the insulating layer 509, a magnet 350 is disposed opposite from the first shadow mask 301. The magnetic force of the magnet 350 attracts the first shadow mask 301 to the support face 25. The first shadow mask 301 is thus positioned at the support face 25 in such a way that the reference face 301r and the support face 25 contact each other. Vacuum deposition is performed in this state. This causes the material for the photoelectric conversion film 518 to enter and deposit in the notch 301n. The photoelectric conversion film 518 having the first sloped face 518t1 is thus formed. The first sloped face 518t1 may have a shape in conformity with the shape of the sloped face 301s.

The second forming method illustrated in FIG. 11 is vacuum deposition using the second shadow mask 302. The second shadow mask 302 has a reference face 302r. The second shadow mask 302 has no sloped face. As seen from the insulating layer 509, the magnet 350 is disposed opposite from the second shadow mask 302. The magnetic force of the magnet 350 attracts the second shadow mask 302 to the support face 25. At this time, however, the magnetic force of the magnet 350 is moderately weak, which causes a lateral end portion 302h of the second shadow mask 302 to deflect away from the support face 25. This creates a gap between the lateral end portion 302h and the support face 25. Vacuum deposition is performed in this state. The material for the photoelectric conversion film 518 thus enters the gap. That is, the material for the photoelectric conversion film 518 gradually enters and deposits in the gap between the lateral end portion 302h and the support face 25. The photoelectric conversion film 518 having the first sloped face 518t1 is thus formed.

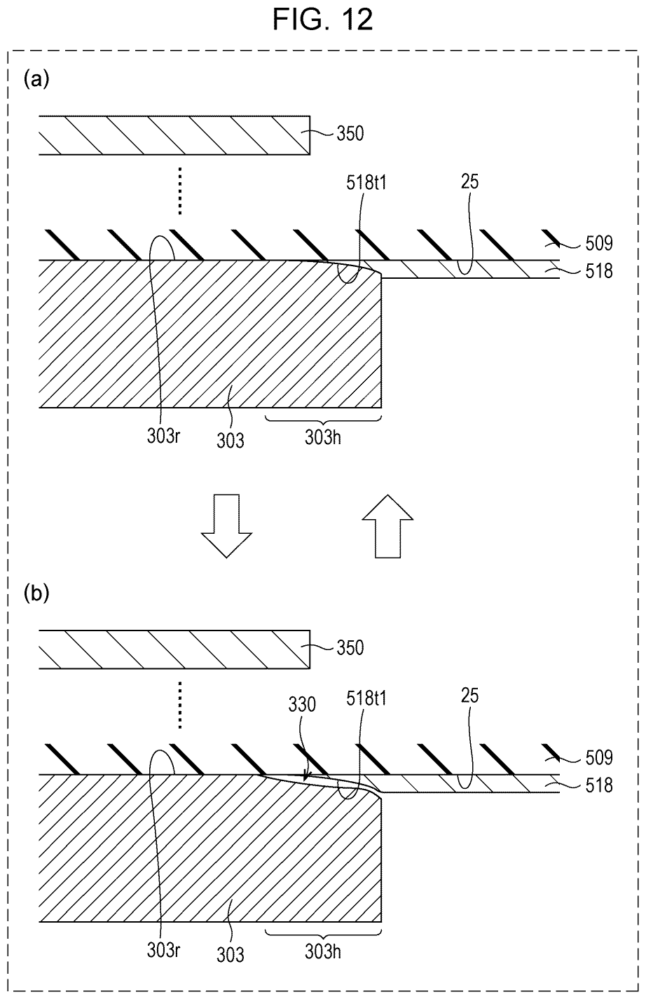

The third forming method illustrated in FIG. 12 is vacuum deposition using the third shadow mask 303. The third shadow mask 303 has a reference face 303r. The third shadow mask 303 has no sloped face. As seen from the insulating layer 509, the magnet 350 is disposed opposite from the third shadow mask 303. The magnetic force of the magnet 350 attracts the third shadow mask 303 to the support face 25. In this state, the third shadow mask 303 is caused to vibrate while vacuum deposition is performed. The vibration causes the state illustrated in FIG. 12(a) and the state illustrated in FIG. 12(b) to appear alternately. In the state illustrated in FIG. 12(a), a lateral end portion 303h of the third shadow mask 303 undergoes relatively small deflection, and the lateral end portion 303h is thus located relatively close to the support face 25. In the state illustrated in FIG. 12(b), the lateral end portion 303h undergoes relatively large deflection, and the lateral end portion 303h is thus located relatively far from the support face 25. In the state illustrated in FIG. 12(b), a gap 330 is created between the lateral end portion 303h and the support face 25. As the third shadow mask 303 vibrates in such a way that the state in FIG. 12(a) and the state in FIG. 12(b) appear alternately, the material for the photoelectric conversion film 518 enters the gap 330 intermittently. That is, the material for the photoelectric conversion film 518 gradually enters and deposits in the gap between the lateral end portion 303h and the support face 25. The photoelectric conversion film 518 having the first sloped face 518t1 is thus formed. The vibration may, for example, occur as the material for the photoelectric conversion film 518 collides with the support face 25 and/or the third shadow mask 303.

Although the photoelectric converter and the manufacturing method therefor according to the present disclosure have been describe above based on embodiments, the above embodiments are not intended to be limiting of the photoelectric converter and the manufacturing method therefor according to the present disclosure. The scope of the present disclosure also encompasses: other embodiments achieved by combining any constitute elements in the above embodiments; modifications obtained through various conceivable changes made to the above embodiments by those skilled in the art without departing from the scope and spirit of the present disclosure; and a variety of equipment incorporating the photoelectric converter according to the present disclosure. For example, as described in International Publication No. 2019/239851, a conductive film may be used as the light-shielding film 522, and the counter electrode 519 and the connection electrode 537 may be electrically connected via the light-shielding film 522. For such implementation as well, the photoelectric conversion film 518 having the shape according to the present disclosure can be used.

The photoelectric converter according to the present disclosure may be used for image sensors and imaging devices that are intended for various applications.

What is claimed is:

1. A photoelectric converter comprising:
a support face; and
a photoelectric conversion film disposed at the support face,
wherein in a first cross-section parallel to a perpendicular direction that is perpendicular to the support face,
the photoelectric conversion film has a first sloped face, and
when an inclination angle of the first sloped face relative to a first parallel direction parallel to the support face is defined as a first slope angle,
the first slope angle is greater than 0° and less than or equal to 5°.

2. The photoelectric converter according to claim 1, wherein the first slope angle is greater than 0° and less than or equal to 1°.

3. The photoelectric converter according to claim 1,
wherein the photoelectric conversion film has an upper face, and
wherein in the first cross-section, the first sloped face is located between the upper face and the support face with respect to the perpendicular direction.

4. The photoelectric converter according to claim 3,
wherein in the first cross-section,
when:
a position of a lower end of the first sloped face is defined as a reference position;
a distance between the upper face and the support face with respect to the perpendicular direction is defined as a reference distance;
10% of the reference distance is defined as a first distance;
a position on the first sloped face that is located upwardly away from the support face by the first distance in the perpendicular direction is defined as a first position;
a distance between the reference position and the first position with respect to the first parallel direction is defined as a first parallel distance; and
a distance between the reference position and the first position with respect to the perpendicular direction is defined as a first perpendicular distance,
the first slope angle is an arctangent of a ratio of the first perpendicular distance to the first parallel distance.

5. The photoelectric converter according to claim 3,
wherein in the first cross-section,
when:
a position of a lower end of the first sloped face is defined as a reference position;
a distance between the upper face and the support face with respect to the perpendicular direction is defined as a reference distance;
20% of the reference distance is defined as a second distance;
a position on the first sloped face that is located upwardly away from the support face by the second distance in the perpendicular direction is defined as a second position;
a distance between the reference position and the second position with respect to the first parallel direction is defined as a second parallel distance; and
a distance between the reference position and the second position with respect to the perpendicular direction is defined as a second perpendicular distance,
the first slope angle is an arctangent of a ratio of the second perpendicular distance to the second parallel distance.

6. The photoelectric converter according to claim 3,
wherein in the first cross-section,
when:
a position of a lower end of the first sloped face is defined as a reference position;
a distance between the upper face and the support face with respect to the perpendicular direction is defined as a reference distance;
90% of the reference distance is defined as a third distance;
a position on the first sloped face that is located upwardly away from the support face by the third distance in the perpendicular direction is defined as a third position;
a distance between the reference position and the third position with respect to the first parallel direction is defined as a third parallel distance; and
a distance between the reference position and the third position with respect to the perpendicular direction is defined as a third perpendicular distance,
the first slope angle is an arctangent of a ratio of the third perpendicular distance to the third parallel distance.

7. The photoelectric converter according to claim 3,
wherein in the first cross-section, when a distance between the upper face and the support face with respect to the perpendicular direction is defined as a reference distance,
the reference distance is greater than or equal to 0.1 μm and less than or equal to 1.0 μm.

8. The photoelectric converter according to claim 1,
wherein the photoelectric conversion film has a lower face facing the support face, and
wherein in the first cross-section,
the first sloped face has a first portion and a second portion, the first portion being connected to the lower face, the second portion being located above the first portion, and
when:
an inclination angle of the first portion relative to the first parallel direction is defined as a first angle; and
an inclination angle of the second portion relative to the first parallel direction is defined as a second angle,
the first angle is less than the second angle.

9. The photoelectric converter according to claim 1,
wherein the photoelectric conversion film has a lower face facing the support face, and
wherein in the first cross-section, the first sloped face has a concave portion connected to the lower face.

10. The photoelectric converter according to claim 1, further comprising an electrode,
wherein the photoelectric conversion film is located above the support face,
wherein the electrode is located above the photoelectric conversion film, and
wherein when a region that overlaps the first sloped face in plan view is defined as a first overlap region,
in the first cross-section, the first overlap region of the electrode has at least one face with an inclination angle greater than 0° and less than or equal to 5° relative to the first parallel direction.

11. The photoelectric converter according to claim 1, further comprising an insulating film,
wherein the photoelectric conversion film is located above the support face,
wherein the insulating film is located above the photoelectric conversion film, and
wherein when a region that overlaps the first sloped face in plan view is defined as a first overlap region,
in the first cross-section, the first overlap region of the insulating film has at least one face with an inclination angle greater than 0° and less than or equal to 5° relative to the first parallel direction.

12. The photoelectric converter according to claim 1, further comprising a light-shielding film,
wherein the photoelectric conversion film is located above the support face,
wherein the light-shielding film is located above the photoelectric conversion film, and
wherein when a region that overlaps the first sloped face in plan view is defined as a first overlap region,
in the first cross-section, the first overlap region of the light-shielding film has at least one face with an inclination angle greater than 0° and less than or equal to 5° relative to the first parallel direction.

13. The photoelectric converter according to claim 1, further comprising
an insulating layer,
wherein the support face includes an upper face of the insulating layer.

14. The photoelectric converter according to claim 1,
wherein in the first cross-section,
the photoelectric conversion film has a second sloped face,
the first sloped face is located in an end portion of the photoelectric conversion film that projects toward one side in the first parallel direction,
the second sloped face is located in an end portion of the photoelectric conversion film that projects toward an other side in the first parallel direction, and
when an inclination angle of the second sloped face relative to the first parallel direction is defined as a second slope angle,
the second slope angle is greater than 0° and less than or equal to 5°.

15. The photoelectric converter according to claim 1,
wherein in a second cross-section parallel to the perpendicular direction and orthogonal to the first cross-section,
the photoelectric conversion film has a third sloped face, and
when an inclination angle of the third sloped face relative to a second parallel direction parallel to the support face is defined as a third slope angle,
the third slope angle is greater than 0° and less than or equal to 5°.

16. The photoelectric converter according to claim 15,
wherein in the second cross-section,
the photoelectric conversion film has a fourth sloped face,
the third sloped face is located in an end portion of the photoelectric conversion film that projects toward one side in the second parallel direction,
the fourth sloped face is located in an end portion of the photoelectric conversion film that projects toward an other side in the second parallel direction, and
when an inclination angle of the fourth sloped face relative to the second parallel direction is defined as a fourth slope angle,
the fourth slope angle is greater than 0° and less than or equal to 5°.

17. An image sensor comprising:
the photoelectric converter according to claim 1; and
a detection circuit that extracts a signal, the signal being generated through photoelectric conversion in the photoelectric conversion film.
